(19) United States
(12) Patent Application Publication
(10) Pub. No.: US 2025/0107074 A1
(43) Pub. Date: Mar. 27, 2025

(54) SEMICONDUCTOR DEVICE

(71) Applicant: Kioxia Corporation, Tokyo (JP)

(72) Inventors: Yusuke MUTO, Yokkaichi Mie (JP); Kazuhiro KATONO, Mie Mie (JP); Tomoki HARADA, Yokkaichi Mie (JP); Akifumi GAWASE, Kuwana Mie (JP)

(21) Appl. No.: 18/829,236

(22) Filed: Sep. 9, 2024

(30) Foreign Application Priority Data
Sep. 21, 2023 (JP) 2023-155684

(51) Int. Cl. H10B 12/00

(52) U.S. Cl. CPC H10B 12/485; H10B 12/33; H10B 12/05

(57) ABSTRACT

A semiconductor device includes a first electrode, a first oxide semiconductor in contact with the first electrode at one end of the first oxide semiconductor, the first oxide semiconductor extending in a first direction that intersects with a surface of the first electrode, a first insulator surrounding a side surface of the first oxide semiconductor, a first conductor surrounding at least a part of a side surface of the first insulator, a second conductor in contact with another end of the first oxide semiconductor, a third conductor on the second conductor, and a fourth conductor on the third conductor. The third conductor and the fourth conductor include a first metallic element, and the second conductor and the third conductor include oxygen.

### CROSS-REFERENCE TO RELATED APPLICATIONS

This application is based upon and claims the benefit of priority from Japanese Patent Application No. 2023-155684, filed Sep. 21, 2023, the entire contents of which are incorporated herein by reference.

### FIELD

Embodiments relate to a semiconductor device.

### BACKGROUND

Semiconductor devices are used in various electronic devices.

### BRIEF DESCRIPTION OF THE DRAWINGS

FIG. 1 illustrates a sectional view of a semiconductor device according to a first embodiment.

FIG. 2 illustrates a plan view of the semiconductor device.

FIG. 3 illustrates a sectional view of the semiconductor device along line III-III in FIG. 2.

FIG. 4 illustrates a sectional view of the semiconductor device along line IV-IV in FIG. 2.

FIG. 5 illustrates a sectional view of the semiconductor device along line V-V in FIG. 3.

FIG. 6 illustrates a flow chart of manufacturing processes of the semiconductor device.

FIG. 7 illustrates a sectional structure in the course of manufacturing the semiconductor device.

FIG. 8 illustrates a sectional structure in the course of manufacturing the semiconductor device.

FIG. 9 illustrates a sectional structure in the course of manufacturing the semiconductor device.

FIG. 10 illustrates a sectional structure in the course of manufacturing the semiconductor device.

FIG. 11 sectional structure in the course of manufacturing the semiconductor device.

FIG. 12 illustrates a sectional structure in the course of manufacturing the semiconductor device.

FIG. 13 illustrates a sectional structure in the course of manufacturing the semiconductor device.

FIG. 14 illustrates a sectional structure in the course of manufacturing the semiconductor device.

FIG. 15 illustrates a sectional structure in the course of manufacturing the semiconductor device.

FIG. 16 illustrates a sectional structure of a semiconductor device according to a first modification of the first embodiment.

FIG. 17 illustrates a sectional structure of a semiconductor device according to a second embodiment.

FIG. 18 illustrates a flow chart of manufacturing processes of the semiconductor device.

FIG. 19 illustrates a sectional structure in the course of manufacturing the semiconductor device.

FIG. 20 illustrates a sectional structure of a semiconductor device according to a first modification of the second embodiment.

### DETAILED DESCRIPTION

Embodiments of the present disclosure improve performance of a semiconductor device.

In general, according to one embodiment, a semiconductor device comprises: a first electrode; a first oxide semiconductor in contact with the first electrode at one end of the first oxide semiconductor, the first oxide semiconductor extending in a first direction that intersects with a surface of the first electrode; a first insulator surrounding a side surface of the first oxide semiconductor; a first conductor surrounding at least a part of a side surface of the first insulator; a second conductor in contact with another end of the first oxide semiconductor; a third conductor on the second conductor; and a fourth conductor on the third conductor. The third conductor and the fourth conductor include a first metallic element, and the second conductor and the third conductor include oxygen.

The embodiments will now be described with reference to drawings. In the following description, those components that have substantially the same functionality and configuration have like reference signs, and the description may not be repeated. Further numerals or characters may follow the reference signs so that two or more components that have substantially the same functionality and configuration are mutually distinguished.

The drawings are schematic, and the relationship between a thickness and planar dimensions, the ratio of thicknesses of layers, and the like may be different from the actual ones. Accordingly, specific thicknesses or dimensions should be determined in consideration of the following description. There may be portions included, in which dimensional relationships or ratios are different from one drawing to another. Unless excluded explicitly or self-evidently, all the descriptions for one embodiment apply also to the description for other embodiments. Each embodiment is intended to illustrate an apparatus or a method for realizing technical ideas of the embodiment and the technical ideas of the embodiment are not intended to limit materials, shapes, structures, arrangements, and the like of components to those described below.

Although intended to indicate sameness, the terms “essentially the same”, “substantially the same”, “substantially even”, and “substantially level” as used in the specification still indicate that the subjects are not perfectly the same and tolerate errors due to the limitation of manufacturing technology and/or measurement technology.

### [1] First Embodiment

A semiconductor device 100 according to a first embodiment will now be described.

### [1-1] Configuration (Structure)

An example of the structure of the semiconductor device 100 according to the first embodiment will now be described. In the following description, Cartesian coordinate system that is constituted of an X-axis, a Y-axis, and a Z-axis is used. In the following description, a reference indicative of “lower” and derived and related words thereof denote a position indicated by smaller coordinates on the Z-axis, and a reference indicative of “upper” and derived and related words thereof denote a position indicated by larger coordinates on the Z-axis. In plan views, a hatching is applied as needed for the purpose of clarity. The hatching applied to plan views does not necessarily relate to any material or characteristics of a component to which the hatching is applied. In sectional views, some components such as an insulator layer (e.g., an interlayer dielectric), a substrate SU, a wire, and a contact are not illustrated as needed for the purpose of clarity.

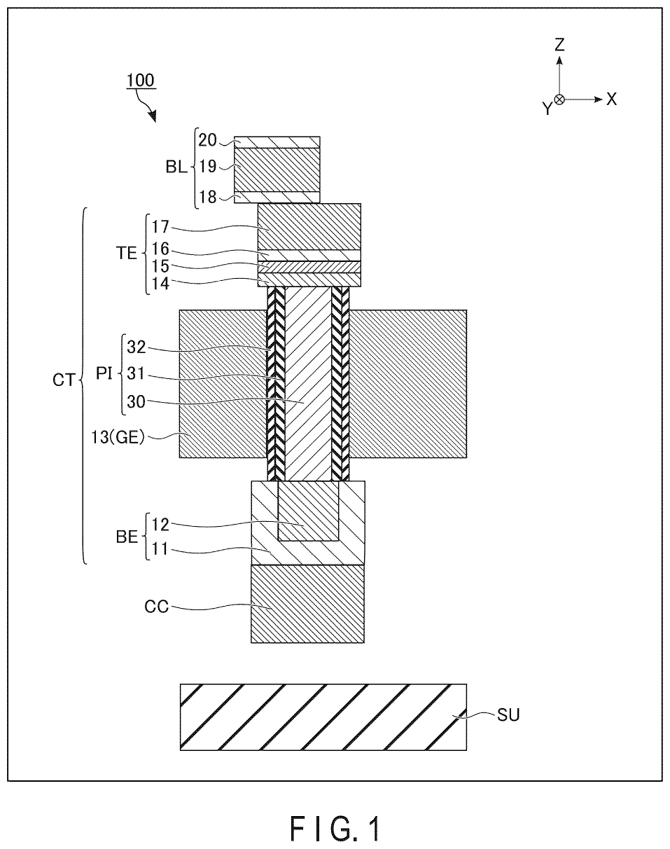

FIG. 1 is a sectional view illustrating an example configuration of the semiconductor device 100 according to the first embodiment. As illustrated in FIG. 1, the semiconductor device 100 includes a substrate SU, a capacitor CC, a lower electrode BE, a pillar PI, an upper electrode TE, a gate electrode GE, and a bit line BL.

For example, the substrate SU is a silicon substrate.

For example, the capacitor CC is a capacitive element. For example, the capacitor CC is provided above the substrate SU. For example, the capacitor CC has a columnar shape extending along the Z-axis. For example, the capacitor CC has a cylindrical shape. For example, the capacitor CC includes a conductive material.

The lower electrode BE is provided on the capacitor CC. For example, the lower electrode BE has a columnar shape.

The pillar PI is provided on the lower electrode BE. For example, the pillar PI has a columnar shape extending along the Z-axis.

The upper electrode TE is provided on the pillar PI. For example, the upper electrode TE has a columnar shape.

The gate electrode GE is provided between the lower electrode BE and the upper electrode TE. The gate electrode GE is in contact with a side surface of the pillar PI. The gate electrode GE will be detailed later.

The bit line BL is provided on the upper electrode TE. The bit line BL extends along the Y-axis. The lower end of the pillar PI is electrically connected to the lower electrode BE, and the upper end of the pillar PI is electrically connected to the upper electrode TE. The upper end of the upper electrode TE and the lower end of the bit line BL are electrically connected to each other.

A set of the lower electrode BE, the gate electrode GE, the pillar PI, and the upper electrode TE functions as a transistor. The lower electrode BE and the upper electrode TE each function as a source electrode or a drain electrode of the transistor. The gate electrode GE functions as a gate electrode of the transistor. The pillar PI functions as a current path or channel of the transistor. Accordingly, a set of the lower electrode BE, the gate electrode GE, the pillar PI, and the upper electrode TE may be hereinafter referred to as a vertical transistor CT because current flows between the lower electrode BE and the upper electrode TE through the pillar PI extending along the Z-axis.

The lower electrode BE includes a first lower electrode layer 11 and a second lower electrode layer 12. For example, the second lower electrode layer 12 has a cylindrical shape and is provided in a central portion of the lower electrode BE. The upper surface of the second lower electrode layer 12 is in contact with the pillar PI as the upper surface of the lower electrode BE.

The second lower electrode layer 12 includes a conductive material. For example, the second lower electrode layer 12 includes conductive oxide. For example, the second lower electrode layer 12 is a conductive oxide layer.

For example, the second lower electrode layer 12 includes indium (In), tin (Sn), and oxygen (O). For example, the second lower electrode layer 12 includes indium tin oxide. For example, the second lower electrode layer 12 is an indium tin oxide layer.

For example, the second lower electrode layer 12 includes tin (Sn) and oxygen (O). For example, the second lower electrode layer 12 includes tin oxide. For example, the second lower electrode layer 12 is a tin oxide layer.

The first lower electrode layer 11 is in contact with surfaces except for the upper surface of the second lower electrode layer 12. That is, the first lower electrode layer 11 is in contact with side surfaces and the lower surface of the second lower electrode layer 12. The lower surface of the first lower electrode layer 11 is in contact with the upper surface of the capacitor CC. For example, the first lower electrode layer 11 includes a third metallic element. For example, the first lower electrode layer 11 includes the third metallic element and nitrogen (N). For example, the first lower electrode layer 11 includes nitride of the third metallic element. For example, the third metallic element is Ti, Sn, Zn, Ru, or Nb. For example, the first lower electrode layer 11 is titanium nitride (TiN).

Provided between an oxide semiconductor 30, which will be described later, and the first lower electrode layer 11, the second lower electrode layer 12 can reduce contact resistance between the oxide semiconductor 30 and the first lower electrode layer 11.

The pillar PI includes the oxide semiconductor 30 and a first gate dielectric 31. The oxide semiconductor 30 is provided on the second lower electrode layer 12. The oxide semiconductor 30 extends along the Z-axis and is provided in a central portion of the pillar PI. For example, the oxide semiconductor 30 is provided in a shape of cylinder. The second lower electrode layer 12 is provided such that it is wider than the oxide semiconductor 30 in an XY-plan view (or a top view) as viewed from the +Z side.

For example, the oxide semiconductor 30 includes zinc (Zn), oxygen (O), and at least one element selected from a group consisting of indium (In), gallium (Ga), silicon (Si), aluminum (Al), and tin (Sn). For example, the oxide semiconductor 30 includes indium (In), gallium (Ga), zinc (Zn), and oxygen (O). For example, the oxide semiconductor 30 includes indium gallium zinc oxide. For example, the oxide semiconductor 30 is indium gallium zinc oxide layer.

For example, the first gate dielectric 31 surrounds the oxide semiconductor 30. For example, the first gate dielectric 31 is provided in a shape of hollow cylinder in the pillar PI. For example, the first gate dielectric 31 includes an insulator such as silicon oxide.

For example, the second gate dielectric 32 surrounds the first gate dielectric 31. For example, the second gate dielectric 32 is provided in a shape of hollow cylinder in the pillar PI. For example, the second gate dielectric 32 includes an insulator such as silicon nitride.

Note that either the first gate dielectric 31 or the second gate dielectric 32 may be omitted.

The upper electrode TE includes a first upper electrode layer 14, a second upper electrode layer 15, a third upper electrode layer 16, and a fourth upper electrode layer 17.

The first upper electrode layer 14 is provided on the oxide semiconductor 30. In other words, the first upper electrode layer 14 is in contact with the upper end of the oxide semiconductor 30. The first upper electrode layer 14 is provided such that it is wider than the oxide semiconductor 30 in an XY-plan view as viewed from the +Z side. For example, the first upper electrode layer 14 includes conductive oxide. For example, the first upper electrode layer 14 includes indium (In), tin (Sn), and oxygen (O). For example, the first upper electrode layer 14 includes indium tin oxide. For example, the first upper electrode layer 14 is indium tin oxide layer.

For example, the first upper electrode layer 14 includes tin (Sn) and oxygen (O). For example, the first upper electrode layer 14 includes tin oxide. For example, the first upper electrode layer 14 is tin oxide layer.

The second upper electrode layer 15 is provided on the first upper electrode layer 14. For example, the second upper electrode layer 15 includes a first metallic element and O. For example, the second upper electrode layer 15 includes oxide of the first metallic element. For example, the second upper electrode layer 15 includes the first metallic element, O, and a first element. For example, the second upper electrode layer 15 includes conductive oxide containing the first metallic element. For example, the first metallic element is Ti, Sn, Zn, Ru, or Nb. For example, the first element is N, Ti, Sn, Zn, Ru, Ta, W, Mo, Al, Ga, Mn, or Mg. For example, the second upper electrode layer 15 is titanium oxide (TiO).

The third upper electrode layer 16 is provided on the second upper electrode layer 15. For example, the third upper electrode layer 16 includes the first metallic element. For example, the third upper electrode layer 16 includes the first metallic element and N. For example, the third upper electrode layer 16 includes nitride of the first metallic element. For example, the third upper electrode layer 16 is titanium nitride (TN).

The fourth upper electrode layer 17 is provided on the third upper electrode layer 16. For example, the fourth upper electrode layer 17 includes tungsten (W). For example, the third upper electrode layer 16 can prevent W contained in the fourth upper electrode layer 17 from diffusing into the second upper electrode layer 15. That is, for example, the third upper electrode layer 16 functions as a barrier metal. For example, the fourth upper electrode layer 17 has a thickness at least three times that of the second upper electrode layer 15 along the Z-axis. Note that the fourth upper electrode layer 17 may be omitted.

Provided between the oxide semiconductor 30 and the second upper electrode layer 15, the first upper electrode layer 14 can reduce contact resistance between the oxide semiconductor 30 and the second upper electrode layer 15.

Provided between the first upper electrode layer 14 and the third upper electrode layer 16, the second upper electrode layer 15 can increase adhesion between the first upper electrode layer 14 and the third upper electrode layer 16. Details will be described in the description of advantageous effects later.

The bit line BL includes conductors 18 to 20. The conductor 18 is provided on the fourth upper electrode layer 17. For example, the conductor 18 includes TiN.

The conductor 19 is provided on the conductor 18. For example, the conductor 19 includes W.

The conductor 20 is provided on the conductor 19. For example, the conductor 20 includes TiN.

For example, the conductors 18 and 20 function as barrier metals. For example, the conductors 18 and 20 can prevent W contained in the conductor 19 from diffusing into adjacent insulator layers and the like. The conductors 18 and 20 may be omitted. The fourth upper electrode layer 17 and the third upper electrode layer 16 may be integrated or the third upper electrode layer 16, the fourth upper electrode layer 17, and the conductor 18 may be integrated.

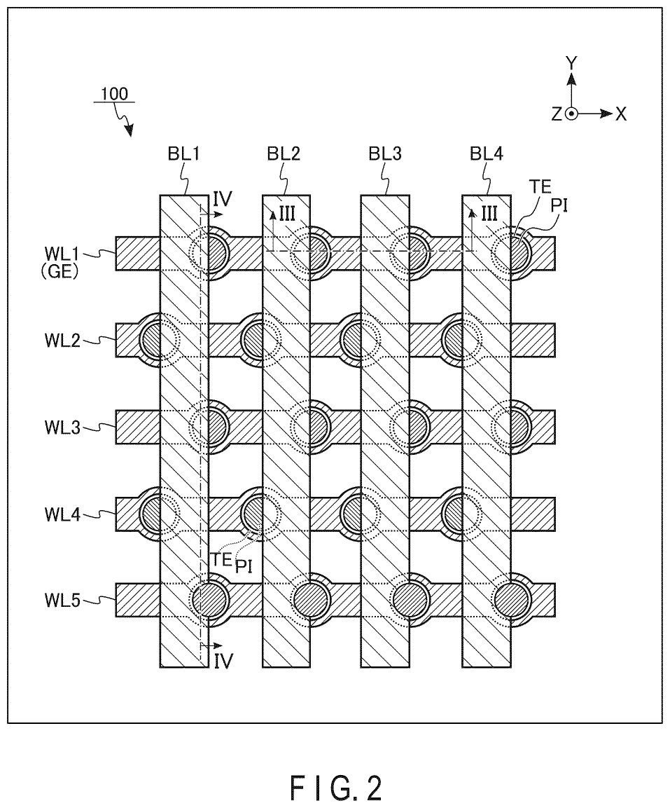

FIG. 2 is a plan view of the semiconductor device 100 according to the first embodiment. As illustrated in FIG. 2, the semiconductor device 100 indicates a plurality of bit lines BL and a plurality of word lines WL and a plurality of pillars PI and a plurality of upper electrodes TE associated with these wires.

A plurality of pillars PI include, for example, 5 rows of pillars PI in the XY-plane. In each row, the pillars PI are arranged along the X-axis. In two rows of pillars PI that are adjacent to each other, the position of each pillar PI in the X direction in one row and the position of each pillar PI in the X direction in the other row are offset from each other. In other words, two rows of pillars PI that are adjacent to each other are positioned in a zigzag manner in the XY-plane. FIG. 2 illustrates an example in which the pillars PI are in 5 rows, while the number and arrangement of the pillars PI are not limited thereto and may be changed as needed. For example, each of the pillars PI functions as one vertical transistor CT.

As illustrated in FIG. 1, each pillar PI and the associated bit line BL are connected via the upper electrode TE. A plurality of bit lines BL, each of which extends along the Y-axis, are arranged along the X-axis. Each bit line BL is positioned to overlap one pillar PI for each row of a plurality of pillars PI. At this time, for example, each bit line BL overlaps each pillar PI of every odd-numbered row on the −X side, and overlaps each pillar PI of every even-numbered row on the +X side.

The bit line BL and the pillar PI are electrically connected to each other. There may be any number of pillars PI overlapping each bit line BL in design.

The gate electrode GE surrounds the pillar PI in an XY-plan view as viewed from the +Z side. That is, the gate electrode GE is provided around the oxide semiconductor 30 and surrounds the oxide semiconductor 30. Accordingly, the semiconductor device 100 has high gate electrostatic controllability. Furthermore, the gate electrode GE includes a portion that is extended along the X-axis. In this example, the gate electrode GE functions as a word line WL.

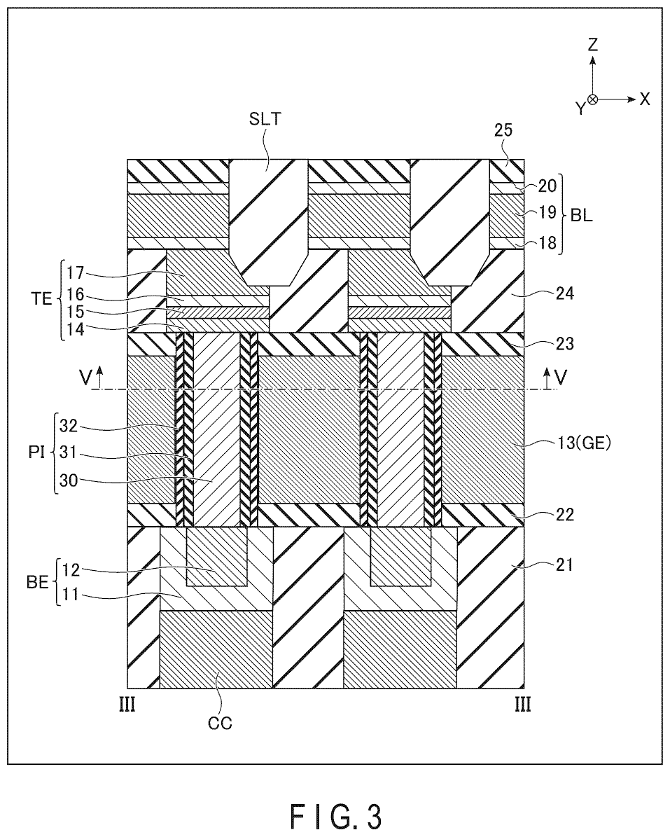

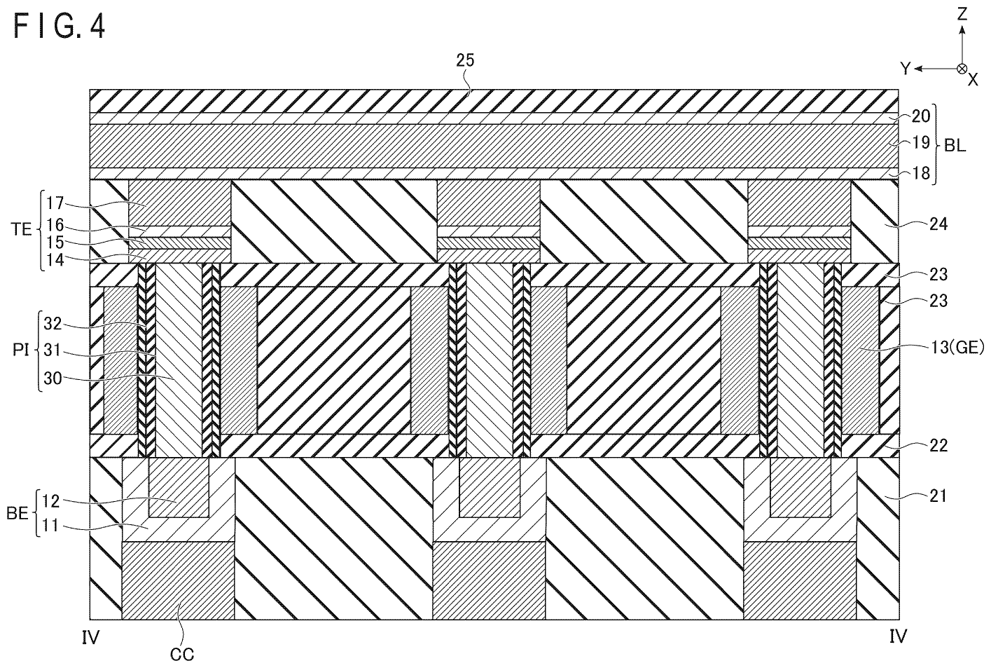

FIG. 3 is a sectional view of the semiconductor device 100 according to the first embodiment along line III-III in FIG. 2. FIG. 4 is a sectional view of the semiconductor device 100 according to the first embodiment along line IV-IV in FIG. 2. As illustrated in FIGS. 3 and 4, the semiconductor device 100 includes the capacitor CC, insulators 21 to 25, the lower electrode BE, the pillar PI, the upper electrode TE, the gate electrode GE, the bit line BL, and a part SLT.

For example, the insulator 21 is provided above the substrate SU, which is not illustrated. An insulator 22 is provided on the insulator 21. A conductor 13 is provided on the insulator 22. An insulator 23 is provided on the conductor 13. An insulator 24 is provided on the insulator 23. A bit line BL is provided on the insulator 24. An insulator 25 is provided on the bit line BL.

The capacitor CC and the lower electrode BE are provided in the insulator 21. For example, the upper surface of the insulator 21 and the upper surface of the lower electrode BE are substantially level with each other, and the lower surface of the insulator 21 and the lower surface of the capacitor CC are substantially level with each other. The lower end of the lower electrode BE is located in the insulator 21 and is in contact with the upper end of the capacitor CC.

The upper electrode TE is provided in the insulator 24. For example, the upper surface of the insulator 24 and the upper surface of the upper electrode TE are substantially level with each other, and the lower surface of the insulator 24 and the lower surface of the upper electrode TE are substantially level with each other.

The pillar PI is provided between the insulator 21 and the insulator 24. A side surface of the pillar PI is in contact with the insulator 22, the conductor 13, and the insulator 23.

The conductors 18 to 20 extend along the Y-axis.

For example, each of the insulators 21 to 25 includes SiO2.

Although omitted in FIGS. 1 and 2, a part SLT is provided between the bit lines BL that are adjacent to each other along the X-axis. A plurality of parts SLT, each of which extends along the Y-axis, are arranged along the X-axis. Insulation is provided by the part SLT between the bit lines BL that are adjacent to each other along the X-axis.

Each part SLT is positioned to overlap one pillar PI for each row of a plurality of pillars PI. At this time, for example, each part SLT overlaps a pillar PI of every odd-numbered row on the +X side, and overlaps a pillar PI of every even-numbered row on the −X side.

The part SLT divides each of the insulator 25 and the conductors 18 to 20. For example, it may be sufficient when the bottom surface of the part SLT reaches the insulator 24. A part of the upper end of the fourth upper electrode layer 17 is in contact with the part SLT. The upper end of the fourth upper electrode layer 17 includes a portion that is in contact with the part SLT and a portion that is in contact with the conductor 18.

For example, each part SLT includes SiO2.

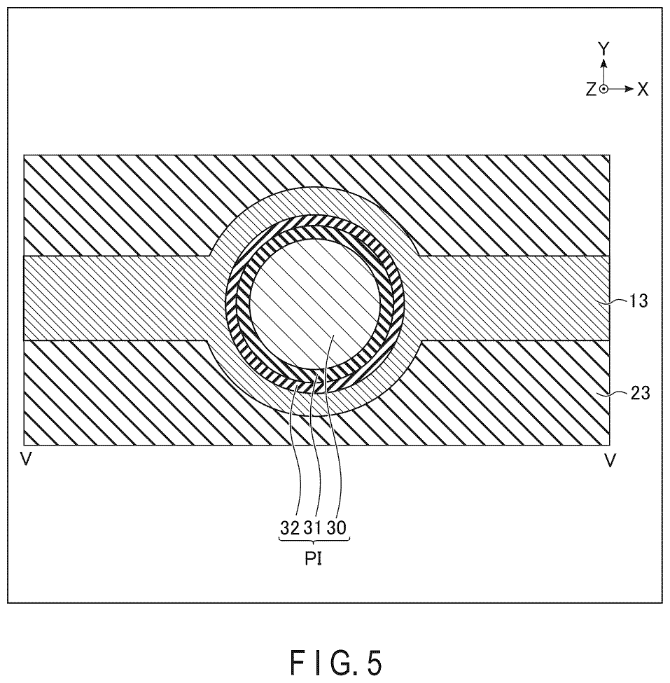

FIG. 5 illustrates a sectional structure of the semiconductor device 100 according to the first embodiment along line V-V in FIG. 3. More specifically, FIG. 5 illustrates a sectional structure of the semiconductor device 100 in a layer that is in parallel to the surface of the substrate SU and includes the gate electrode GE. As illustrated in FIG. 5, in a section including the gate electrode GE, the oxide semiconductor 30 is provided in a central portion of the pillar PI. The first gate dielectric 31 surrounds a side surface of the oxide semiconductor 30. For example, the oxide semiconductor 30 is embedded within the first gate dielectric 31 provided in a shape of a hollow cylinder. The second gate dielectric 32 surrounds a side surface of the first gate dielectric 31.

The conductor 13 includes a portion that surrounds a side surface of the second gate dielectric 32 and a portion that is extended along the X-axis.

As described above, the first gate dielectric 31 and the second gate dielectric 32 are provided between the oxide semiconductor 30 and the conductor 13 that functions as a gate electrode.

In each pillar PI described above, the oxide semiconductor 30 is used as a channel of the semiconductor device 100.

### [1-2] Manufacturing Method of Semiconductor Device 100

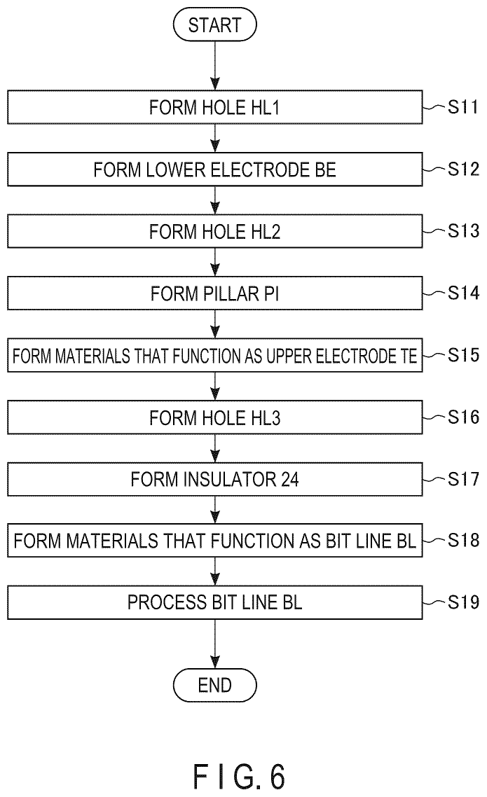

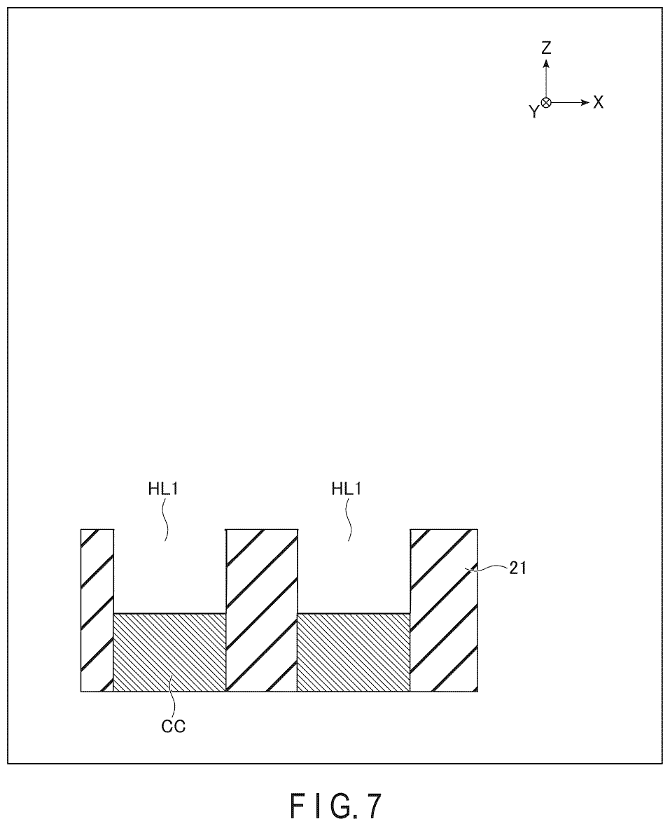

FIG. 6 is a flow chart of manufacturing processes of the semiconductor device 100 according to the first embodiment. FIGS. 7 to 15 each illustrate a sectional structure in the course of manufacturing the semiconductor device 100 according to the first embodiment. FIGS. 7 to 15 each illustrate a section of the same region as FIG. 3. The manufacturing processes with respect to forming the semiconductor device 100 according to the first embodiment will now be described with reference to FIG. 6 as needed. As illustrated in FIG. 6, in the manufacturing method of the semiconductor device 100 according to the first embodiment, the processes of steps S11 to S19 are performed in order.

In the process of step S11, holes HL1 are formed as illustrated in FIG. 7. Specifically, the insulator 21 is first formed above the substrate SU (not illustrated). Next, a region in which the capacitor CC and the lower electrode BE are to be formed is etched, so that each hole HL1 is formed. For example, the hole HL1 is formed through photolithography and anisotropic etching. For example, the reactive ion etching (RIE) is used for the anisotropic etching. Thereafter, the capacitor CC is formed in the lower part of each hole HL1, leaving a region in which the lower electrode BE is to be formed as the hole HL1.

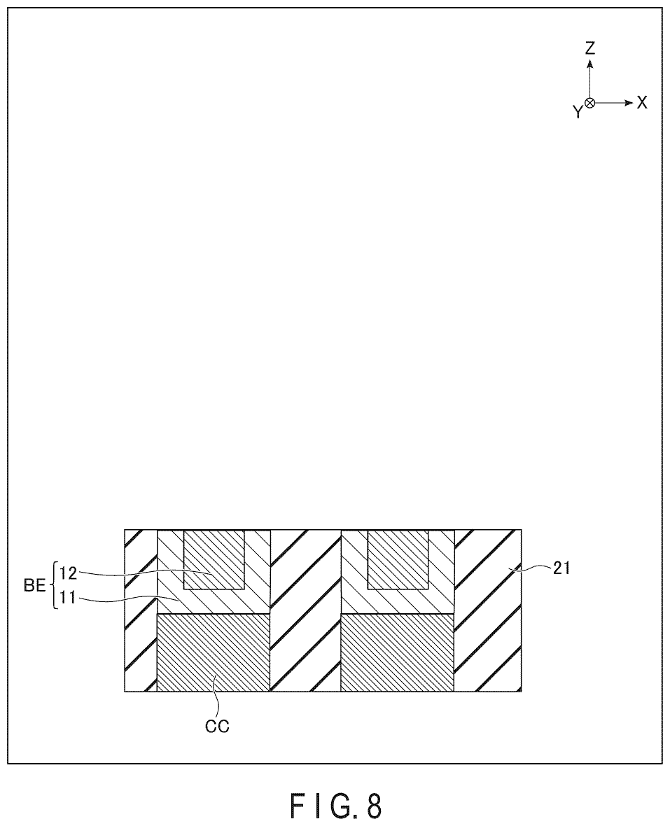

In the process of step S12, the lower electrode BE is formed as illustrated in FIG. 8. The first lower electrode layer 11 is first formed on the bottom and side surfaces of each hole HL1. That is, in each hole HL1, the first lower electrode layer 11 is formed on the upper surface of the capacitor CC and side surfaces of the insulator 21. Next, the second lower electrode layer 12 is embedded in the hole HL1. That is, the second lower electrode layer 12 is formed on the surface of the first lower electrode layer 11 and inside the hole HL1 entirely.

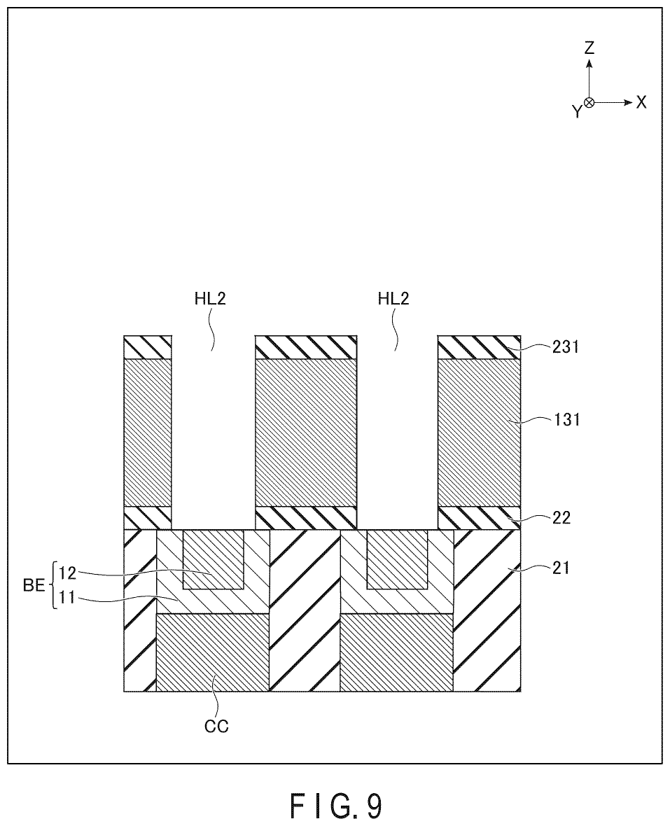

In the process of step S13, holes HL2 are formed as illustrated in FIG. 9. Specifically, the insulator 22, a conductor 131, and an insulator 231 are first formed in order on the upper surfaces of the insulator 21 and the lower electrode BE. For example, sputtering is used to form the conductor 131. Once the subsequent processes are performed, the conductor 13 is formed from a part of the conductor 131. That is, the conductor 131 is etched, so that the conductor 13 is formed. For example, the insulator 231 is formed in a region including a region in which the insulator 23 is to be formed.

Next, a region in which the pillar PI is to be formed is etched, so that each hole HL2 is formed. For example, the hole HL2 is formed to reach the upper surface of the lower electrode BE from the upper surface of the insulator 231 through photolithography and anisotropic etching. For example, RIE is used for the anisotropic etching.

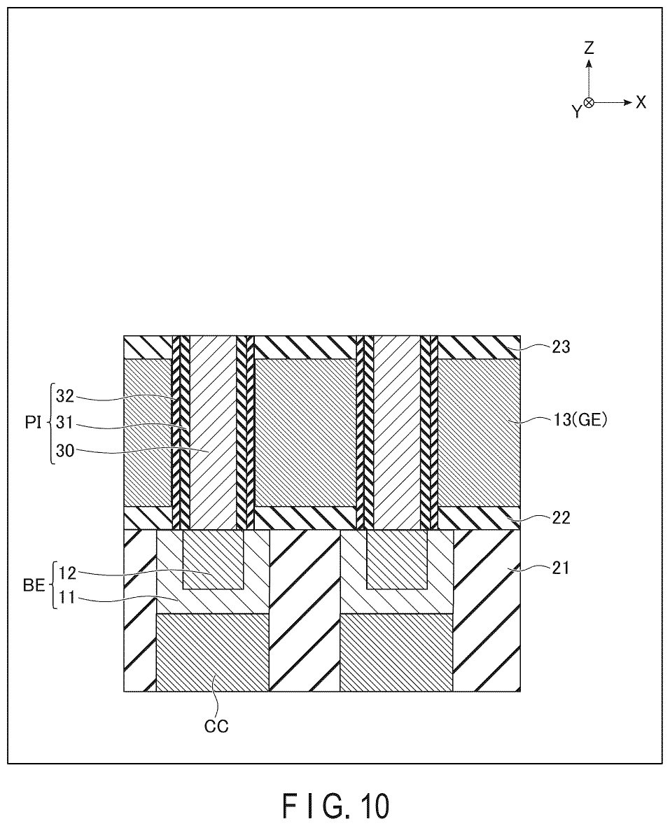

In the process of step S14, the pillars PI are formed as illustrated in FIG. 10. The second gate dielectric 32 is formed on the surface of each hole HL2. Thereafter, the first gate dielectric 31 is formed on the surface of the second gate dielectric 32. For example, the first gate dielectric 31 and the second gate dielectric 32 are formed as films through CVD and the like.

Next, for example, through anisotropic etching such as RIE, for example, a part of the first gate dielectric 31 and the second gate dielectric 32 formed on the bottom of the hole HL2 is removed. In this way, in the hole HL2, the surface of the second lower electrode layer 12 is exposed.

Thereafter, the oxide semiconductor 30 is formed. For example, the oxide semiconductor 30 is embedded within the hole HL2 entirely through ALD and the like. The oxide semiconductor 30 comes into contact with the second lower electrode layer 12 on the bottom surface of the hole HL2. The oxide semiconductor 30 comes into contact with the first gate dielectric 31.

Next, the conductor 131 is removed except for a region in which the conductor 13 is to be formed. An insulator 232, which is not illustrated, is formed in a portion from which the conductor 131 has been removed. The upper surface of the insulator 232 and the upper surface of the insulator 231 formed in step S13 are substantially level with each other. An insulator constituted of the insulator 232 and the insulator 231 will be hereinafter referred to as the insulator 23. In this way, the conductor 13 and the insulator 23 are formed.

Thereafter, the oxide semiconductor 30 formed on the insulator 23 is removed. Each of the upper surfaces of the insulator 23, the first gate dielectric 31, the second gate dielectric 32, and the oxide semiconductor 30 may be planarized through CMP.

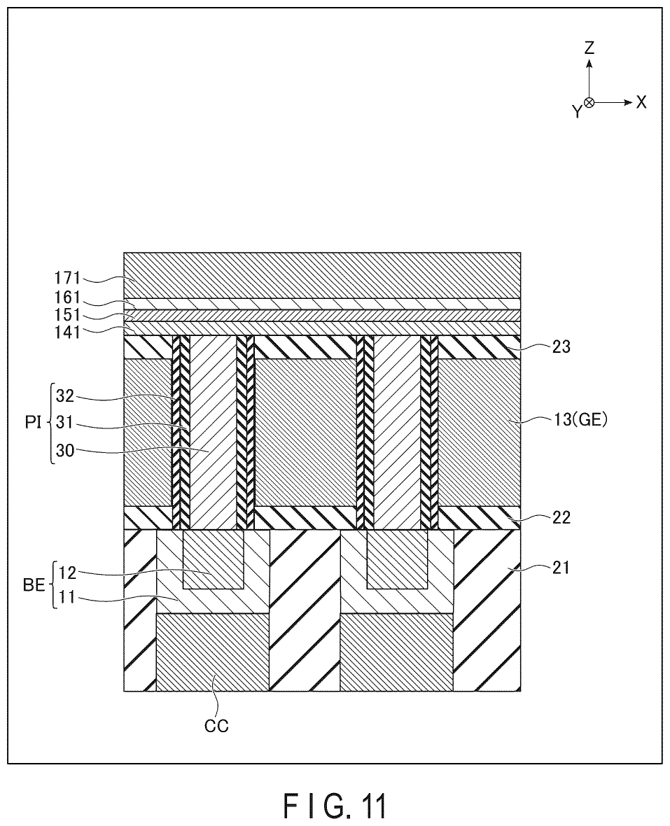

In the process of step S15, materials that function as the upper electrode TE is formed as illustrated in FIG. 11. Specifically, a first upper electrode layer 141 is first formed on the upper surfaces of the insulator 23 and the pillar PI. Next, a second upper electrode layer 151 is formed on the upper surface of the first upper electrode layer 141. Next, a third upper electrode layer 161 is formed on the upper surface of the second upper electrode layer 151. Next, a fourth upper electrode layer 171 is formed on the upper surface of the third upper electrode layer 161. For example, the first upper electrode layer 141, the second upper electrode layer 151, the third upper electrode layer 161, and the fourth upper electrode layer 171 are formed through sputtering.

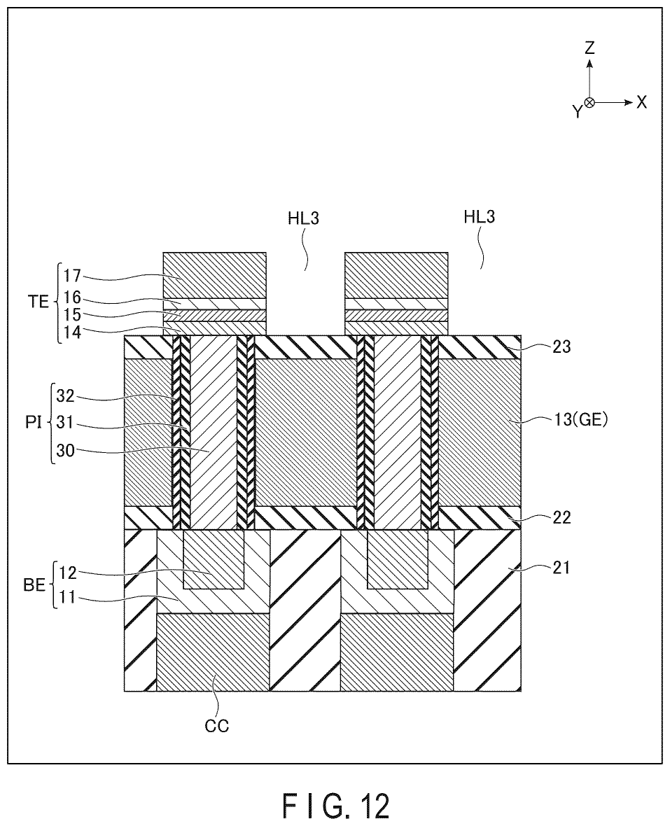

In the process of step S16, holes HL3 are formed as illustrated in FIG. 12. Each hole HL3 is first formed in a region in which the insulator 24 is to be formed. Specifically, a mask that has an opening of a region in which the hole HL3 is to be formed is formed through photolithography and the like, and the hole HL3 is formed through anisotropic etching using the mask. The formed hole HL3 divides the first upper electrode layer 141, the second upper electrode layer 151, the third upper electrode layer 161, and the fourth upper electrode layer 171, so that the insulator 23 is exposed.

In other words, the first upper electrode layer 141, the second upper electrode layer 151, the third upper electrode layer 161, and the fourth upper electrode layer 171 are removed except for a region in which the upper electrode TE is to be formed. In this way, the first upper electrode layer 14 is formed from a part of the first upper electrode layer 141. That is, a part of the first upper electrode layer 141 is etched, so that the first upper electrode layer 14 is formed. Similarly, the second upper electrode layer 15, the third upper electrode layer 16, and the fourth upper electrode layer 17 are formed from a part of the second upper electrode layer 151, a part of the third upper electrode layer 161, and a part of the fourth upper electrode layer 171, respectively.

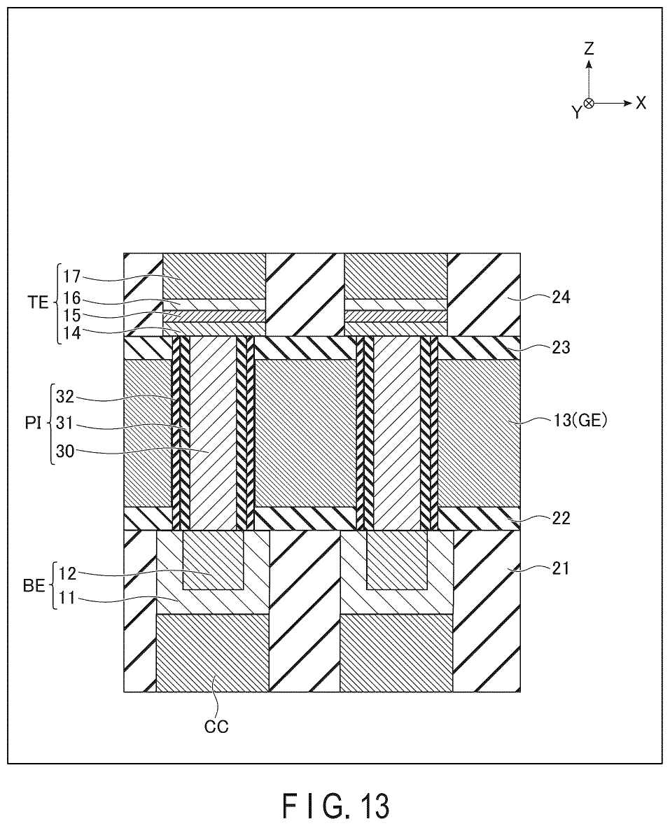

In the process of step S17, the insulator 24 is formed as illustrated in FIG. 13. The insulator 24 is formed to fill each hole HL3, so that the upper electrode TE is formed, extending along the Z-axis in a columnar shape. That is, the insulator 24 is embedded between the upper electrodes TE that are adjacent to each other.

Thereafter, the insulator 24 formed on the upper electrode layer 17 is removed. Each of the upper surfaces of the insulator 24 and the fourth upper electrode layer 17 may be planarized through CMP.

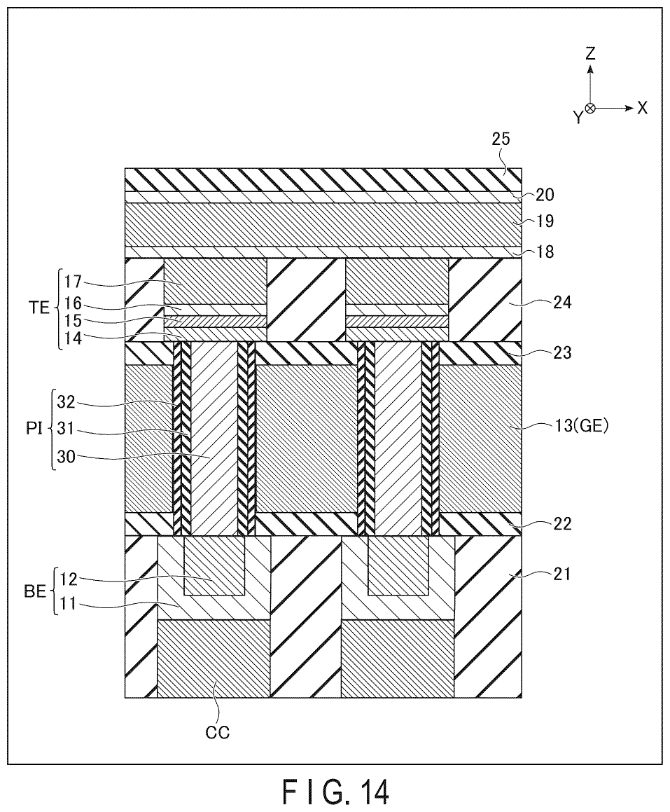

In the process of step S18, materials that function as the bit line BL are formed as illustrated in FIG. 14. Specifically, the conductor 18 is first formed on the upper surfaces of the insulator 24 and the upper electrode TE. Next, the conductor 19 is formed on the upper surface of the conductor 18. Next, the conductor 20 is formed on the upper surface of the conductor 19. Next, the insulator 25 is formed on the upper surface of the conductor 20. For example, the conductors 18 to 20 are formed through sputtering.

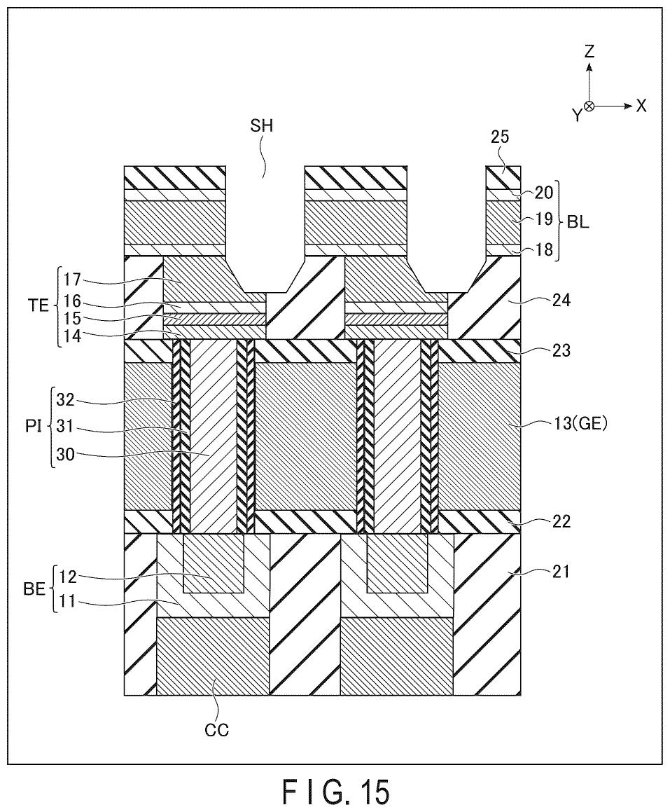

In the process of step S19, the bit line BL is processed as illustrated in FIG. 15. Slits SH are first formed in regions in which the parts SLT are to be formed. Specifically, a mask that has openings of regions in which the slits SH are to be formed is formed through photolithography and the like, and the slits SH are formed through anisotropic etching using the mask.

For example, each slit SH divides each of the insulator 25 and the conductors 18 to 20 to reach the insulator 24. A part of the insulator 24 and the upper electrode layer 17 is exposed by the slit SH. The upper end of the upper electrode layer 17 includes a portion that is in contact with the conductor 18 and a portion that is exposed by the slit SH.

Next, the part SLT is formed to fill the slit SH. The part SLT is positioned to overlap one pillar PI for each row of a plurality of pillars PI in an XY-plan view.

Once the part SLT is formed, the bit lines BL that extend along the Y-axis and are arranged along the X-axis as illustrated in FIGS. 3 and 4 are formed. In other words, the part SLT is embedded between the bit lines BL that are adjacent to each other.

In the manufacturing processes of the semiconductor device 100 according to the first embodiment described above, the semiconductor device 100 is formed. Note that any manufacturing process described above is exemplary only and is not a limitation. For example, any other process may be inserted between the manufacturing processes, and some processes may be omitted or combined. Furthermore, the order of the manufacturing processes may be changed to the extent that no problem occurs.

### [1-3] Advantages of First Embodiment (Advantageous Effects)

According to the semiconductor device 100 according to the first embodiment described above, it is possible to improve performance of the semiconductor device 100. Detailed advantageous effects of the semiconductor device 100 according to the first embodiment will now be described.

As described above, the semiconductor device 100 according to the first embodiment includes the second upper electrode layer 15 between the first upper electrode layer 14 and the third upper electrode layer 16 in the upper electrode TE. A semiconductor device without the second upper electrode layer 15 between the first upper electrode layer 14 and the third upper electrode layer 16 may be hereinafter referred to as a semiconductor device 100r according to a comparative example of the first embodiment.

In the semiconductor device 100r, for example, the first upper electrode layer 14 and the third upper electrode layer 16 are in contact with each other due to lack of the second upper electrode layer 15. In the case in which the first upper electrode layer 14 and the third upper electrode layer 16 are in contact, the adhesion between the two layers may be reduced. The reduced adhesion between the first upper electrode layer 14 and the third upper electrode layer 16 may cause separation between the two layers. Any separation between the first upper electrode layer 14 and the third upper electrode layer 16 may cause a reduction in the migration resistance of the upper electrode TE and an increase in the resistance of the upper electrode TE, for example.

In the meantime, a structure in which layers are stacked as in the upper electrode TE of the embodiment is more susceptible to a reduction in adhesion than a structure as that of the lower electrode BE. In the lower electrode BE, the first lower electrode layer 11 is in contact with the lower surface and side surfaces of the second lower electrode layer 12. In contrast, in the upper electrode TE, the first upper electrode layer 14 is in contact only with the lower surface of the second upper electrode layer 15, and the second upper electrode layer 15 is in contact only with the lower surface of the third upper electrode layer 16. The reason for the reduced adhesion is that the contact area of layers of the upper electrode TE is smaller than the contact area of layers of the lower electrode BE.

The semiconductor device 100 includes the second upper electrode layer 15 between the first upper electrode layer 14 and the third upper electrode layer 16. Since the second upper electrode layer 15 is included, the semiconductor device 100 has an improved adhesion between the second upper electrode layer 15 and the third upper electrode layer 16 and between the first upper electrode layer 14 and the second upper electrode layer 15.

The reason for this is that the first upper electrode layer 14 and the second upper electrode layer 15 include O, and the second upper electrode layer 15 and the third upper electrode layer 16 include the first metallic element described above. That is, O in the first upper electrode layer 14 and the first metallic element in the second upper electrode layer 15 can be bonded together at their interface. Furthermore, In in the first upper electrode layer 14 and O in the second upper electrode layer 15 can be bonded together at their interface. This improves adhesion between the first upper electrode layer 14 and the second upper electrode layer 15.

Next, O in the second upper electrode layer 15 and the first metallic element in the third upper electrode layer 16 can be bonded together at their interface. Furthermore, the first metallic element in the second upper electrode layer 15 and N in the third upper electrode layer 16 can be bonded together at their interface. The first element in the second upper electrode layer 15 and the first metallic element or N in the third upper electrode layer 16 can be bonded together at their interface. This improves adhesion between the second upper electrode layer 15 and the third upper electrode layer 16.

As described above, since the second upper electrode layer 15 that contains O and the first metallic element is inserted between the first upper electrode layer 14 that contains O and the third upper electrode layer 16 that contains the first metallic element, the semiconductor device 100 has an improved adhesion from the first upper electrode layer 14 to the third upper electrode layer 16. With improved adhesion, the semiconductor device 100 may have more improved migration resistance and more improved reliability than the semiconductor device 100r.

### [2] Modifications of First Embodiment

### (First Modification)

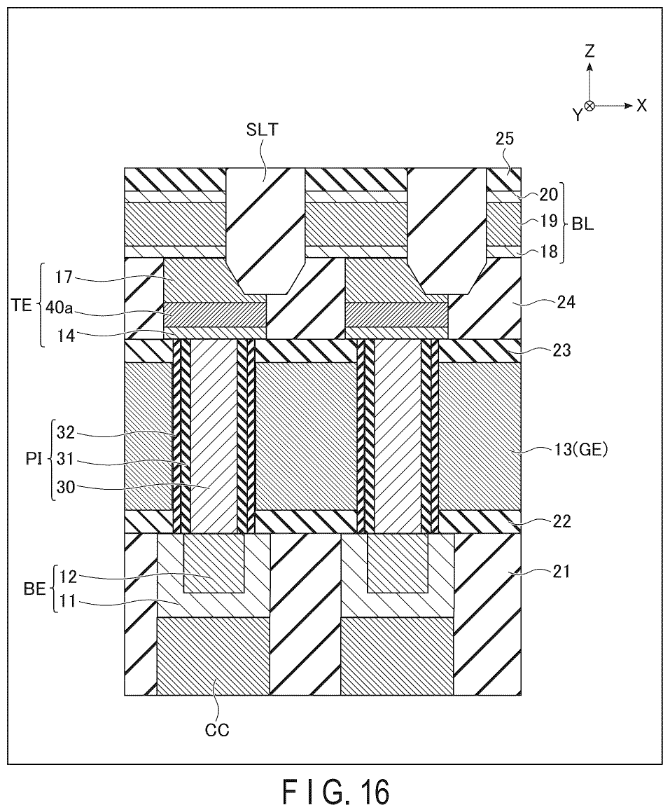

In the upper electrode TE of the semiconductor device 100 according to the first embodiment described above, an example has been illustrated, which includes the second upper electrode layer 15 between the first upper electrode layer 14 and the third upper electrode layer 16. However, in the upper electrode TE according to a first modification of the first embodiment, as illustrated in FIG. 16, the second upper electrode layer 15 and the third upper electrode layer 16 may be integrated into one layer. In other words, an interface between the second upper electrode layer 15 and the third upper electrode layer 16 may be indistinct. An integrated layer of the second upper electrode layer 15 and the third upper electrode layer 16 will be hereinafter referred to as a fifth upper electrode layer 40a. That is, the upper electrode TE according to the first modification of the first embodiment includes the first upper electrode layer 14, the fifth upper electrode layer 40a, and the fourth upper electrode layer 17.

For example, the fifth upper electrode layer 40a includes the first metallic element, O, and N. For example, the fifth upper electrode layer 40a includes oxide of the first metallic element. For example, the fifth upper electrode layer 40a includes nitride of the first metallic element. For example, the fifth upper electrode layer 40a includes the first metallic element, the first element, O, and N. For example, the fifth upper electrode layer 40a includes conductive oxide containing the first metallic element. As in the first embodiment, for example, the first metallic element is Ti, Sn, Zn, Ru, or Nb. As in the first embodiment, for example, the first element is N, Ti, Sn, Zn, Ru, Ta, W, Mo, Al, Ga, Mn, or Mg.

For example, in the fifth upper electrode layer 40a, the concentration of O contained in a region located on a near side to the first upper electrode layer 14 may be larger than the concentration of O contained in a region located on a near side to the fourth upper electrode layer 17 (or a far side from the first upper electrode layer 14).

For example, in the fifth upper electrode layer 40a, the concentration of the first metallic element contained in a region located on a near side to the first upper electrode layer 14 may be smaller than the concentration of the first metallic element contained in a region located on a near side to the fourth upper electrode layer 17.

For example, in the fifth upper electrode layer 40a, the concentration of N contained in a region located on a near side to the first upper electrode layer 14 may be smaller than the concentration of N contained in a region located on a near side to the fourth upper electrode layer 17.

For example, the fifth upper electrode layer 40a includes more titanium oxide (TiO) in a region located on a near side to the first upper electrode layer 14. For example, the fifth upper electrode layer 40a has a composition that is close to TiO2, that is, includes Ti of on the order of 33% in a region located on a near side to the first upper electrode layer 14.

For example, the fifth upper electrode layer 40a includes more titanium nitride (TiN) in a region located on a near side to the fourth upper electrode layer 17. For example, the fifth upper electrode layer 40a has a composition that is close to TiN, that is, includes Ti of on the order of 50% in a region located on a near side to the fourth upper electrode layer 17.

For example, the fifth upper electrode layer 40a includes more titanium oxynitride (TiON) in a region close to the middle between the first upper electrode layer 14 and the fourth upper electrode layer 17.

In the case of such one integrated layer, it is still possible for the fifth upper electrode layer 40a to improve adhesion from the first upper electrode layer 14 to the fifth upper electrode layer 40a as with the second upper electrode layer 15. That is, it would be possible to improve adhesion from the first upper electrode layer 14 to the fifth upper electrode layer 40a if the fifth upper electrode layer 40a was a single layer and had a structure with varying concentrations of the first metallic element, the first element, O, and N along the Z-axis in the layer. That is, the upper electrode TE according to the first modification of the first embodiment can improve migration resistance. This is because adhesion at the interface and a bond within the fifth upper electrode layer 40a can be enhanced because the fifth upper electrode layer 40a includes O, N, and the first metallic element.

### [3] Second Embodiment

A semiconductor device 100b according to a second embodiment will now be described. The semiconductor device 100 of the second embodiment may be hereinafter referred to as the semiconductor device 100b to distinguish it from the semiconductor device 100 of the first embodiment.

### [3-1] Configuration (Structure)

The semiconductor device 100b according to the second embodiment is different from the semiconductor device 100 according to the first embodiment mainly in the structure of the lower electrode BE. The lower electrode BE of the second embodiment may be hereinafter referred to as a lower electrode BEb to distinguish it from the lower electrode BE of the first embodiment. Any other structures of the second embodiment are substantially the same as those in the first embodiment. Differences of the semiconductor device 100b according to the second embodiment from the first embodiment will mainly be described below.

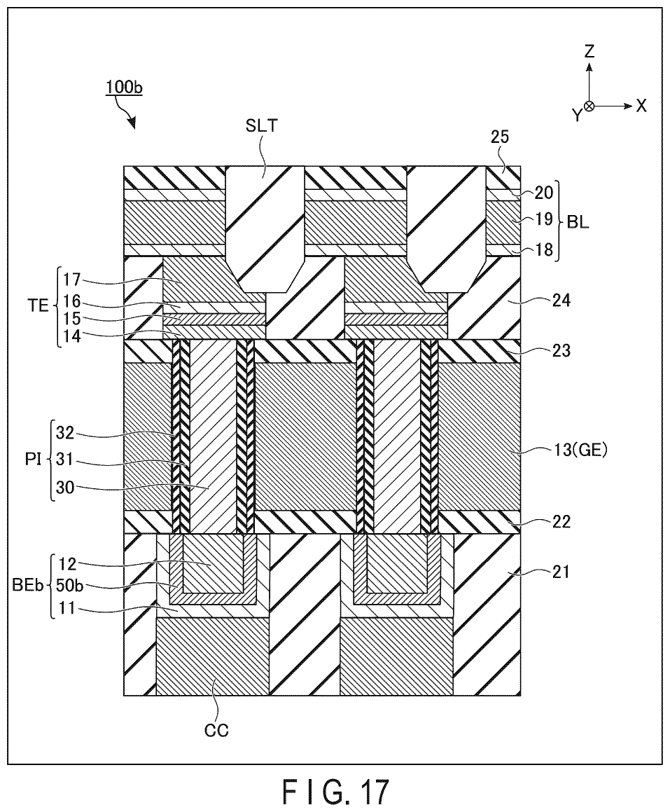

The structure of the lower electrode BEb will be detailed with reference to FIG. 17. FIG. 17 illustrates a sectional structure of the semiconductor device 100b according to the second embodiment. FIG. 17 illustrates a section of the same region as FIG. 3 in the first embodiment.

As illustrated in FIG. 17, the lower electrode BEb in the second embodiment is different from the lower electrode BE in the first embodiment in that it further includes a third lower electrode layer 50b between the first lower electrode layer 11 and the second lower electrode layer 12. The structure of the lower electrode BEb will now be described.

For example, the lower electrode BEb has a cylindrical shape extending along the Z-axis. The lower electrode BEb is located in the insulator 21. For example, the upper surface of the insulator 21 and the upper surface of the lower electrode BEb are substantially level with each other and the lower surface of the insulator 21 and the lower surface of the capacitor CC are substantially level with each other. The lower end of the lower electrode BEb is located in the insulator 21 and is in contact with the upper end of the capacitor CC.

The lower electrode BEb includes the first lower electrode layer 11, the second lower electrode layer 12, and the third lower electrode layer 50b. For example, the second lower electrode layer 12 has a cylindrical shape and is provided in a central portion of the lower electrode BEb. The upper surface of the second lower electrode layer 12 is substantially level with the upper surface of the insulator 21. The upper end of the second lower electrode layer 12 is in contact with the lower end of the pillar PI.

The second lower electrode layer 12 includes a conductive material. For example, the second lower electrode layer 12 includes conductive oxide. For example, the second lower electrode layer 12 is a conductive oxide layer.

For example, the second lower electrode layer 12 includes indium (In), tin (Sn), and oxygen (O). For example, the second lower electrode layer 12 includes indium tin oxide. For example, the second lower electrode layer 12 is an indium tin oxide layer.

For example, the second lower electrode layer 12 includes tin (Sn) and oxygen (O). For example, the second lower electrode layer 12 includes tin oxide. For example, the second lower electrode layer 12 is a tin oxide layer.

Provided between the oxide semiconductor 30 and the third lower electrode layer 50b, which will be described later, the second lower electrode layer 12 can reduce contact resistance between the oxide semiconductor 30 and the third lower electrode layer 50b.

The third lower electrode layer 50b is in contact with surfaces except for the upper surface of the second lower electrode layer 12. That is, the third lower electrode layer 50b is in contact with side surfaces and the lower surface of the second lower electrode layer 12. For example, the third lower electrode layer 50b includes a fourth metallic element and O. For example, the third lower electrode layer 50b includes oxide of the fourth metallic element. For example, the third lower electrode layer 50b includes the fourth metallic element, O, and the second element. For example, the third lower electrode layer 50b includes conductive oxide containing the fourth metallic element. As with the first metallic element, for example, the fourth metallic element is Ti, Sn, Zn, Ru, or Nb. As with the first element, for example, the second element is N, Ti, Sn, Zn, Ru, Ta, W, Mo, Al, Ga, Mn, or Mg. For example, the third lower electrode layer 50b is titanium oxide (TiO).

The fourth metallic element contained in the lower electrode BEb may be the same element as the first metallic element contained in the upper electrode TE. The second element contained in the lower electrode BEb may be the same element as the first element contained in the upper electrode TE.

The first lower electrode layer 11 is in contact with surfaces except for the upper surface of the third lower electrode layer 50b. That is, the first lower electrode layer 11 is in contact with side surfaces and the lower surface of the third lower electrode layer 50b. The lower surface of the first lower electrode layer 11 is in contact with the upper surface of the capacitor CC. For example, the first lower electrode layer 11 includes the fourth metallic element. For example, the first lower electrode layer 11 includes the fourth metallic element and N. For example, the first lower electrode layer 11 includes nitride of the fourth metallic element. For example, the first lower electrode layer 11 is titanium nitride (TiN).

### [3-2] Manufacturing Method of Semiconductor Device 100b

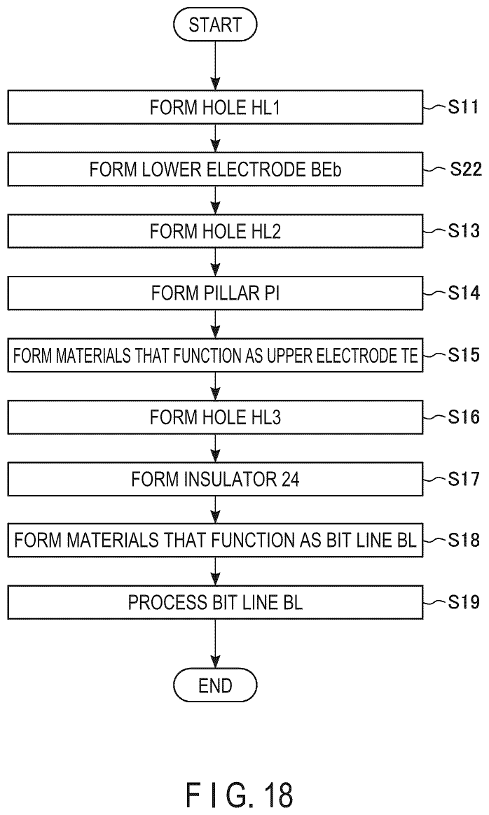

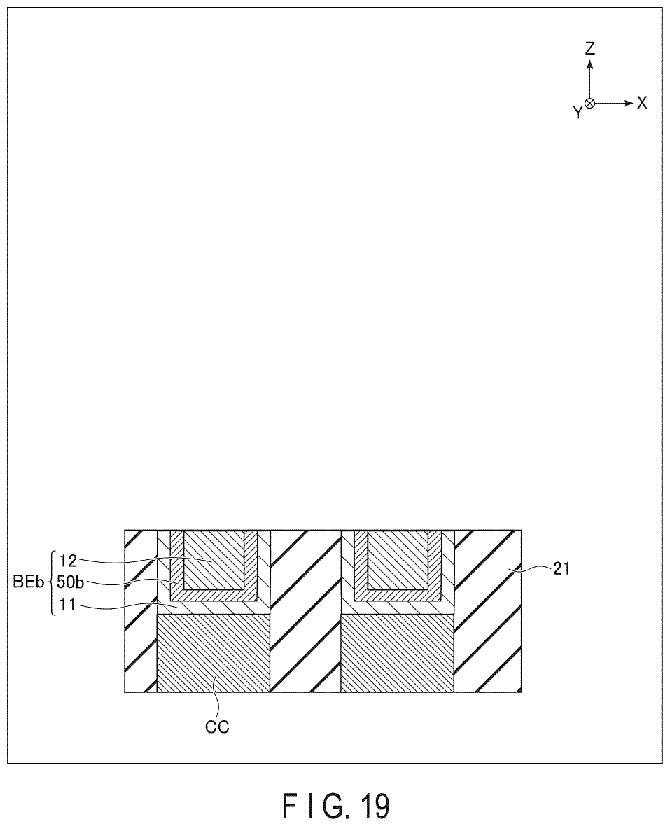

FIG. 18 is a flow chart of manufacturing processes of the semiconductor device 100b according to the second embodiment. FIG. 19 illustrates a sectional structure of the semiconductor device 100b according to the second embodiment in the course of manufacturing. FIG. 19 illustrates a section of the same region as FIG. 8. The manufacturing process to form the semiconductor device 100b according to the second embodiment will now be described with reference to FIG. 18.

As illustrated in FIG. 18, for example, in the manufacturing method of the semiconductor device 100b according to the second embodiment, the processes of steps S11, S22, and S13 to S19 are performed in order.

The process of step S11 is first performed as in the first embodiment.

Next, in the process of step S22, the lower electrode BEb is formed as illustrated in FIG. 19. The first lower electrode layer 11 is first formed on the bottom and side surfaces of the hole HL1. That is, in the hole HL1, the first lower electrode layer 11 is formed on the upper surface of the capacitor CC and side surfaces of the insulator 21. Next, the third lower electrode layer 50b is formed on surfaces of the first lower electrode layer 11. Next, the second lower electrode layer 12 is embedded in the hole HL1. That is, the second lower electrode layer 12 is formed on the surface of the third lower electrode layer 50b and inside the hole HL1 entirely.

Next, the processes of steps S13 to S19 are performed in order as in the first embodiment.

The semiconductor device 100b is formed through the manufacturing processes of the semiconductor device 100b according to the second embodiment described above. Note that any manufacturing process described above is exemplary only and is not a limitation. For example, any other process may be inserted between the manufacturing processes, and some processes may be omitted or combined. Furthermore, the order of the manufacturing processes may be changed to the extent that no problem occurs.

### [3-3] Advantages of Second Embodiment (Advantageous Effects)

According to the semiconductor device 100b according to the second embodiment described above, it is possible to improve performance of the semiconductor device 100b as in the first embodiment.

As described above, the semiconductor device 100b according to the second embodiment includes the third lower electrode layer 50b between the first lower electrode layer 11 and the second lower electrode layer 12 in the lower electrode BEb. Since the third lower electrode layer 50b is included, the semiconductor device 100b has an improved adhesion between the first lower electrode layer 11 and the third lower electrode layer 50b and between the third lower electrode layer 50b and the second lower electrode layer 12.

The reason for this is that the second lower electrode layer 12 and the third lower electrode layer 50b include O, and the third lower electrode layer 50b and the first lower electrode layer 11 have the fourth metallic element as in the first embodiment. That is, O in the second lower electrode layer 12 and the fourth metallic element in the third lower electrode layer 50b can be bonded together at their interface. Furthermore, In in the second lower electrode layer 12 and O in the third lower electrode layer 50b can be bonded together at their interface. This improves adhesion between the second lower electrode layer 12 and the third lower electrode layer 50b.

Next, O in the third lower electrode layer 50b and the fourth metallic element in the first lower electrode layer 11 can be bonded together at their interface. Furthermore, the fourth metallic element in the third lower electrode layer 50b and N in the first lower electrode layer 11 can be bonded together at their interface. The second element in the third lower electrode layer 50b and the fourth metallic element or N in the first lower electrode layer 11 can be bonded together at their interface. This improves adhesion between the third lower electrode layer 50b and the first lower electrode layer 11.

As described above, since the third lower electrode layer 50b that contains O and the fourth metallic element is inserted between the second lower electrode layer 12 that contains O and the first lower electrode layer 11 that contains the fourth metallic element, the lower electrode BEb has an improved adhesion from the second lower electrode layer 12 to first lower electrode layer 11. With improved adhesion, the lower electrode BEb may have improved migration resistance and improved reliability.

### [4] Modification of Second Embodiment

### (First Modification)

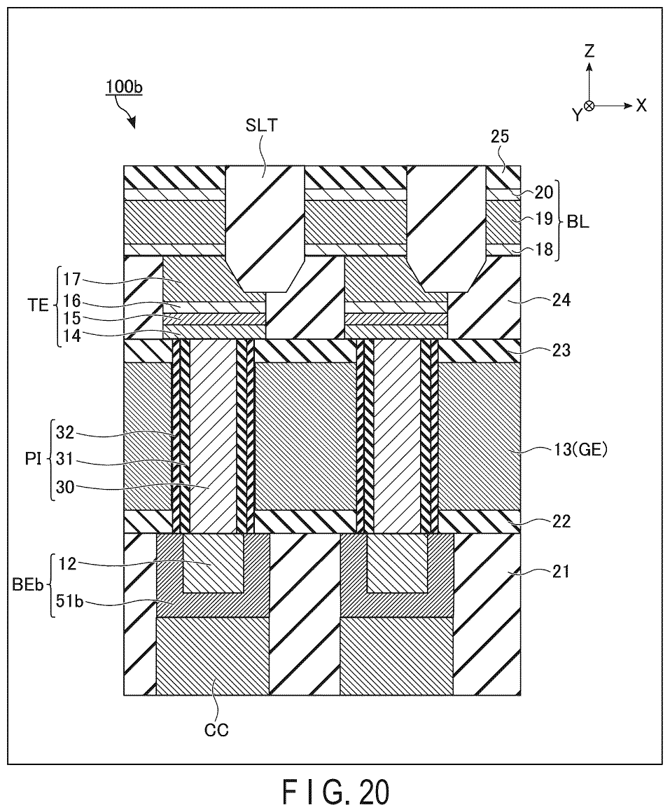

In the lower electrode BEb of the semiconductor device 100b according to the second embodiment described above, an example has been illustrated, which includes the third lower electrode layer 50b between the first lower electrode layer 11 and the second lower electrode layer 12. However, in the lower electrode BEb according to a first modification of the second embodiment, as illustrated in FIG. 20, the third lower electrode layer 50b and the first lower electrode layer 11 may be integrated into one layer. In other words, an interface between the third lower electrode layer 50b and the first lower electrode layer 11 may be indistinct. An integrated layer of the third lower electrode layer 50b and the first lower electrode layer 11 will be hereinafter referred to as a fourth lower electrode layer 51b. That is, the lower electrode BEb according to the first modification of the second embodiment includes the second lower electrode layer 12 and the fourth lower electrode layer 51b.

For example, the fourth lower electrode layer 51b includes the fourth metallic element, O, and N. For example, the fourth lower electrode layer 51b includes oxide of the fourth metallic element. For example, the fourth lower electrode layer 51b includes nitride of the fourth metallic element. For example, the fourth lower electrode layer 51b includes the fourth metallic element, the second element, O, and N. For example, the fourth lower electrode layer 51b includes conductive oxide containing the fourth metallic element. As in the first embodiment, for example, the fourth metallic element is Ti, Sn, Zn, Ru, or Nb. As in the first embodiment, for example, the second element is N, Ti, Sn, Zn, Ru, Ta, W, Mo, Al, Ga, Mn, or Mg.

For example, in the fourth lower electrode layer 51b, the concentration of O contained in a region located on a near side to the second lower electrode layer 12 may be larger than the concentration of O contained in a region located on a far side from the second lower electrode layer 12.

For example, in the fourth lower electrode layer 51b, the concentration of the fourth metallic element contained in a region located on a near side to the second lower electrode layer 12 may be smaller than the concentration of the fourth metallic element contained in a region located on a far side from the second lower electrode layer 12.

For example, in the fourth lower electrode layer 51b, the concentration of N contained in a region located on a near side to the second lower electrode layer 12 may be smaller than the concentration of N contained in a region located on a far side from the second lower electrode layer 12.

For example, the fourth lower electrode layer 51b includes more titanium oxide (TiO) in a region located on a near side to the second lower electrode layer 12. For example, the fourth lower electrode layer 51b has a composition that is close to TiO2, that is, includes Ti of on the order of 33% in a region located on a near side to the second lower electrode layer 12.

For example, the fourth lower electrode layer 51b includes more titanium nitride (TiN) in a region located on a far side from the second lower electrode layer 12. For example, the fourth lower electrode layer 51b has a composition that is close to TiN, that is, includes Ti of on the order of 50% in a region located on a far side from the second lower electrode layer 12.

For example, the fourth lower electrode layer 51b includes more titanium oxynitride (TION) in a region located in the middle between a region close to the second lower electrode layer 12 and a region far from the second lower electrode layer 12.

In the case of such one integrated layer, it is still possible for the fourth lower electrode layer 51b to improve adhesion from the second lower electrode layer 12 to the fourth lower electrode layer 51b as with the third lower electrode layer 50b. That is, it would be possible to improve adhesion from the second lower electrode layer 12 to the fourth lower electrode layer 51b if the fourth lower electrode layer 51b was a single layer and had a structure with varying concentrations of the fourth metallic element, second element, O, and N in the layer. That is, the lower electrode BEb according to the first modification of the second embodiment can improve migration resistance. This is because adhesion at the interface and a bond within the fourth lower electrode layer 51b can be enhanced because the fourth lower electrode layer 51b includes O, N, and the fourth metallic element.

### [4] Other Modifications and so on

In the first and second embodiments, the structures of the semiconductor devices 100 and 100b may be any other structure. The structure of the first embodiment may be applied to the second embodiment. Only a part or a combination of more than one of the structures illustrated in the modifications of the first embodiment and the second embodiment may be applied to the first embodiment and the second embodiment.

The pillar PI may have a tapered shape or an inverse tapered shape, or may have a shape that is bulging in the middle portion.

As used in the specification, the term “connection” indicates that connection is established electrically and does not exclude another element interposed in between, for example. The term “electrically connected” may hold true when an insulator is interposed in between to the extent that operation is possible similarly to being electrically connected.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device comprising:
a first electrode;
a first oxide semiconductor in contact with the first electrode at one end of the first oxide semiconductor, the first oxide semiconductor extending in a first direction that intersects with a surface of the first electrode;
a first insulator surrounding a side surface of the first oxide semiconductor;
a first conductor surrounding at least a part of a side surface of the first insulator;
a second conductor in contact with another end of the first oxide semiconductor;
a third conductor on the second conductor; and
a fourth conductor on the third conductor, wherein
the third conductor and the fourth conductor include a first metallic element, and
the second conductor and the third conductor include oxygen.

2. The semiconductor device according to claim 1, wherein
the first metallic element is Ti, Sn, Zn, Ru, or Nb.

3. The semiconductor device according to claim 2, wherein
the third conductor further includes N, Ti, Sn, Zn, Ru, Ta, W, Mo, Al, Ga, Mn, or Mg.

4. The semiconductor device according to claim 1, wherein
the first oxide semiconductor and the second conductor include a second metallic element.

5. The semiconductor device according to claim 4, wherein
the second metallic element is In.

6. The semiconductor device according to claim 1, wherein
the fourth conductor further includes nitrogen.

7. The semiconductor device according to claim 1, wherein
the first electrode includes:
a fifth conductor in contact with the one end of the first oxide semiconductor on an upper surface of the fifth conductor, and
a sixth conductor in contact with a lower surface of the fifth conductor,
the first oxide semiconductor, the second conductor, and the fifth conductor include a second metallic element, and
the sixth conductor includes a third metallic element.

8. The semiconductor device according to claim 1, wherein
the first electrode includes:
a fifth conductor in contact with the one end of the first oxide semiconductor on an upper surface of the fifth conductor,
a sixth conductor in contact with a lower surface of the fifth conductor, and
a seventh conductor in contact with a lower surface of the sixth conductor,
the sixth conductor and the seventh conductor include a second metallic element, and
the fifth conductor and the sixth conductor include oxygen.

9. The semiconductor device according to claim 8, wherein
the sixth conductor is in contact with a lower surface and a side surface of the fifth conductor, and
the seventh conductor is in contact with a lower surface and a side surface of the sixth conductor.

10. The semiconductor device according to claim 8, wherein
the first metallic element and the second metallic element are the same.

11. The semiconductor device according to claim 8, wherein
the second metallic element is Ti, Sn, Zn, Ru, or Nb.

12. The semiconductor device according to claim 11, wherein
the sixth conductor further includes N, Ti, Sn, Zn, Ru, Ta, W, Mo, Al, Ga, Mn, or Mg.

13. The semiconductor device according to claim 8, wherein
the first oxide semiconductor, the second conductor, and the fifth conductor include a third metallic element.

14. The semiconductor device according to claim 13, wherein
the third metallic element is In.

15. The semiconductor device according to claim 1, wherein
the first electrode includes:
a fifth conductor in contact with the one end of the first oxide semiconductor on an upper surface of the fifth conductor, and
a sixth conductor in contact with a lower surface of the fifth conductor,
the sixth conductor includes a second metallic element and nitrogen,
the fifth conductor and the sixth conductor include oxygen,
the first oxide semiconductor, the second conductor, and the fifth conductor include a third metallic element,
the first metallic element and the second metallic element are Ti, Sn, Zn, Ru, or Nb, and
the third metallic element is In.

16. The semiconductor device according to claim 15, wherein
in the sixth conductor, a concentration of oxygen in a region closer to the fifth conductor is larger than a concentration of oxygen in a region farther from the fifth conductor, and a concentration of nitrogen in a region closer to the fifth conductor is smaller than a concentration of nitrogen in a region farther from the fifth conductor.

17. The semiconductor device according to claim 15, wherein
the first metallic element and the second metallic element are the same.

18. The semiconductor device according to claim 1, wherein
the first oxide semiconductor includes Zn, O and at least one element selected from a group consisting of In, Ga, Si, Al, and Sn.

19. A semiconductor device comprising:
a first electrode;
a first oxide semiconductor in contact with the first electrode at one end of the first oxide semiconductor, the first oxide semiconductor extending in a first direction that intersects with a surface of the first electrode;
a first insulator surrounding a side surface of the first oxide semiconductor;
a first conductor surrounding at least a part of a side surface of the first insulator;
a second conductor in contact with another end of the first oxide semiconductor; and
a third conductor on the second conductor, wherein
the third conductor includes a first metallic element and nitrogen,
the second conductor and the third conductor include oxygen,
the first oxide semiconductor and the second conductor include a second metallic element,
the first metallic element is Ti, Sn, Zn, Ru, or Nb, and
the second metallic element is In.

20. The semiconductor device according to claim 19, wherein
in the third conductor, a concentration of oxygen in a region closer to the second conductor is larger than a concentration of oxygen in a region farther from the second conductor, and a concentration of nitrogen in a region closer to the second conductor is smaller than a concentration of nitrogen in a region farther from the second conductor.
